(19) United States
(12) Patent Application Publication
(10) Pub. No.: US 2025/0197199 A1
(43) Pub. Date: Jun. 19, 2025

(54) PROCESS FOR MANUFACTURING MICROELECTROMECHANICAL DEVICES WITH CHAMBERS SEALED AT DIFFERENT PRESSURES AND MICROELECTROMECHANICAL DEVICE THEREBY MANUFACTURED

(71) Applicant: STMicroelectronics International N.V., Geneva (CH)

(72) Inventors: Federico VERCESI, Milano (IT); Giorgio ALLEGATO, Monza (IT); Lorenzo CORSO, Ruginello (IT); Mikel AZPEITIA URQUIA, Milano (IT); Matteo GARAVAGLIA, Magenta (IT)

(73) Assignee: STMicroelectronics International N.V., Geneva (CH)

(21) Appl. No.: 18/968,911

(22) Filed: Dec. 4, 2024

(30) Foreign Application Priority Data
Dec. 15, 2023 (IT) 102023000026853

(51) Int. Cl. B81C 1/00; B81B 7/00

(52) U.S. Cl. CPC B81C 1/00293; B81B 7/0041; B81B 2201/0235; B81B 2201/0242

(57) ABSTRACT

A process for manufacturing microelectromechanical devices includes forming a dielectric layer and a structural layer on a substrate of a first semiconductor wafer and forming a first and a second microelectromechanical device in the structural layer. The first and second microelectromechanical devices are sealed respectively in a first chamber and in a second chamber at a first pressure. The first chamber is fluidically coupled to an external environment through the substrate and sealed at a second pressure different from the first pressure. To fluidically couple the first chamber to the outside, there are formed a stop layer between the dielectric layer and the structural layer and a cavity fluidically coupled to the first chamber in the dielectric layer. A channel is formed by etching the substrate in a position corresponding to the cavity and the stop layer, and the etching of the substrate is ended against the stop layer.

### BACKGROUND

### Technical Field

The present disclosure relates to a process for manufacturing microelectromechanical devices with chambers sealed at different pressures and a microelectromechanical device thereby manufactured.

### Description of the Related Art

As is known, different microelectromechanical devices incorporated and sealed in a same package are used in many applications. For example, it is very common to integrate uniaxial or multiaxial gyroscopes and accelerometers into the same chip and therefore into the same package.

A frequent issue is linked to the fact that the devices may have optimal operating conditions very different from each other, as in the case of gyroscopes and accelerometers. In fact, in order to reduce consumption due to air friction damping, it is preferable to have the gyroscopes work in an environment having low pressure, typically comprised between 0.1 mbar and 1 mbar. The gyroscopes are maintained constantly oscillating in resonance and low-pressure conditions allow the maintenance of the oscillations, reducing damping and dissipated energy. Accelerometers, on the other hand, normally operate under higher pressure conditions, for example between 1 mbar and a few atmospheres. Similar issues also arise with other types of devices operating under different conditions, for example resonators, wake-up systems, geophones or bolometers in combination with gyroscopes or accelerometers.

A possible solution consists in including different devices in a same cavity or chamber of the package, wherein a pressure level corresponding to a trade-off between the preferred operating pressures is present. Solutions of this type are relatively simple to implement but may be unsatisfactory and affect performance.

According to a different solution, the microelectromechanical devices are included in respective sealed and non-communicating chambers. In practice, the devices, for example gyroscopes and accelerometers, are manufactured in a first wafer, while, in a second wafer, caps are provided, and cavities are formed in positions corresponding to respective sensors. In the cavities intended for devices operating at lower pressure, a layer of an absorbent material or getter is also deposited. When the second wafer is bonded to the first wafer, for example by glass frit bonding or other wafer bonding technique, or at a later time with a dedicated step, the getter is thermally activated and absorbs the non-noble gases present in the chamber, reducing pressure. In this manner chambers sealed at different pressures may be obtained and all the devices may operate under preferred pressure conditions.

However, even this solution is not free from limitations. Firstly, especially when particularly high pressures are desired in one of the chambers, the amount of available gaseous nitrogen may saturate the getter and, in this case, the pressure target in the chamber may not be achieved. On the other hand, to include an amount of getter sufficient to prevent saturation, the dimensions (base area and/or height) of the chamber may be greater than what would be sufficient for the sole microelectromechanical devices.

Furthermore, during manufacturing the getter may be activated prematurely during the wafer bonding steps, before the chambers are completely sealed. In this case, the getter may also absorb gas from the higher-pressure chamber (cross-talk), creating a double drawback. On the one hand, in fact, the pressure of the getter-free chamber decreases and in any case the final pressure value is not accurately predictable. On the other hand, the getter may more easily saturate and therefore even in the low-pressure chamber the atmosphere may not reach the desired level.

### BRIEF SUMMARY

The present disclosure is directed to providing one or more embodiments of a microelectromechanical accelerometer that allows the limitations described to be overcome or at least mitigated.

The present disclosure is directed to one or more embodiments of a process for manufacturing microelectromechanical devices and one or more embodiments of a microelectromechanical device.

For example, at least one embodiment a process for manufacturing microelectromechanical devices is summarized as including: on a first semiconductor wafer comprising a substrate of semiconductor material, forming a dielectric layer, a structural layer and a stop layer between the dielectric layer and the structural layer, the substrate being selectively etchable with respect to the stop layer; forming a first microelectromechanical device and a second microelectromechanical device in the structural layer; sealing the first microelectromechanical device and the second microelectromechanical device respectively in a first chamber and in a second chamber at a first pressure; fluidically coupling the first chamber to an external environment through the substrate; and sealing the first chamber at a second pressure different from the first pressure; wherein fluidically coupling comprises: forming a cavity fluidically coupled to the first chamber in the dielectric layer between the substrate and a portion of the stop layer; forming a channel through the substrate in a position corresponding to the cavity and the portion of the stop layer; and ending the etching of the substrate against the stop layer.

For example, at least one embodiment of a microelectromechanical device is summarized as including:

### BRIEF DESCRIPTION OF THE SEVERAL VIEWS OF THE FIGURES

For a better understanding of the present disclosure, preferred embodiments are provided, by way of non-limiting example, with reference to the attached drawings, wherein:

FIG. 1 is a section through a semiconductor wafer in an initial processing step of a process for manufacturing microelectromechanical devices in accordance with an embodiment of the present disclosure;

FIG. 2 shows an enlarged detail of the section of FIG. 1 in a subsequent processing step of the present process;

FIG. 3 is a top-plan view of a further enlarged detail of the wafer of FIG. 2;

FIG. 4 is a top-plan view of a detail of a semiconductor wafer in an intermediate processing step of a microelectromechanical process in accordance with a variant of the present disclosure;

FIGS. 5 and 6 show the detail of FIG. 2, in subsequent processing steps;

FIGS. 7-9 show the section of FIG. 1 in subsequent processing steps;

FIG. 10 shows the view of FIG. 3 in a subsequent processing step;

FIGS. 11-14 show the section of FIG. 1 in subsequent processing steps;

FIG. 15 shows the view of FIG. 3 in a subsequent processing step;

FIG. 16 is a cross-section through a microelectromechanical device in accordance with an embodiment of the present disclosure, obtained with the process illustrated in FIGS. 1-15;

FIGS. 17 and 18 show a section through a semiconductor wafer in initial processing steps of a process for manufacturing microelectromechanical devices in accordance with a different embodiment of the present disclosure;

FIG. 19 shows an enlarged detail of the section of FIG. 17 in a subsequent processing step of the present process;

FIG. 20 is a top-plan view of a further enlarged detail of the wafer of FIG. 2;

FIG. 21 shows the detail of FIG. 19, in subsequent processing steps;

FIG. 22 shows the view of FIG. 20 in a subsequent processing step;

FIGS. 23-24 show the detail of FIG. 19 in subsequent processing steps;

FIG. 25 shows the view of FIG. 20 in a subsequent processing step;

FIGS. 26-28 show the section of FIG. 17 in subsequent processing steps;

FIG. 29 shows the view of FIG. 20 in a subsequent processing step;

FIG. 30 is a cross-section through a microelectromechanical device in accordance with a different embodiment of the present disclosure, obtained with the process illustrated in FIGS. 17-29.

### DETAILED DESCRIPTION

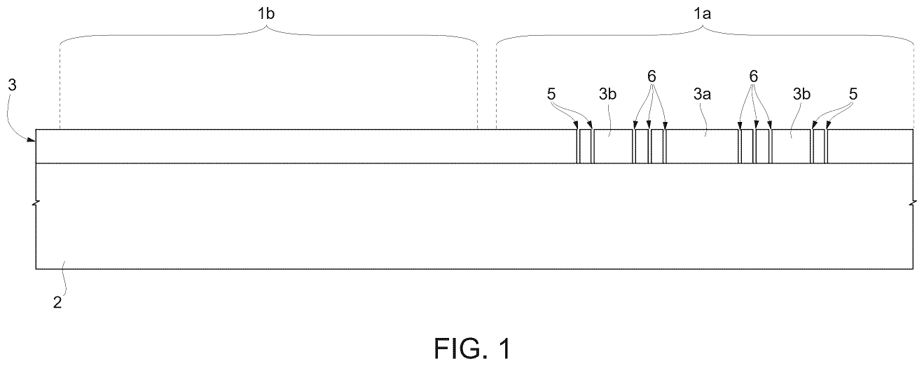

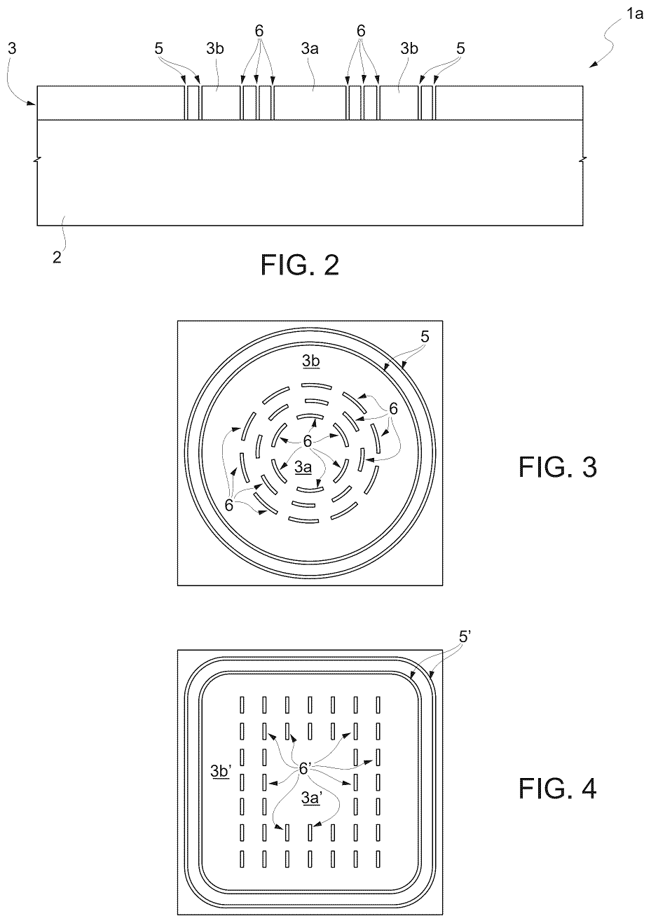

With reference to FIG. 1, a semiconductor wafer 1 comprises a substrate 2, for example of monocrystalline silicon. The wafer 1 is intended to accommodate microstructures of microelectromechanical devices and hereinafter it will be referred to as microstructure wafer 1. More in detail, a first region of the microstructure wafer 1, indicated by 1a, is intended to accommodate a first microelectromechanical sensor operating at a first pressure, for example a gyroscope, and a second region of the microstructure wafer 1, indicated by 1b, is intended to accommodate a second microelectromechanical sensor operating at a second pressure, higher than the first pressure, for example an accelerometer. However, it is understood that other microelectromechanical devices that require different operating pressures, such as resonators and wake-up systems, may be integrated into the substrate 2.

Initially, a dielectric layer 3 of silicon oxide is deposited on the substrate 2 and is selectively etched in the first region 1a to form first trenches 5 and second trenches 6, which will then serve for the formation of anchors. The first trenches 5 extend continuously along respective closed paths nested one inside the other. In the embodiment described herein, in particular two circular and concentric first trenches 5 are opened.

The second trenches 6 are enclosed inside the first trenches 5 and, in one embodiment, are organized in arrays which extend on closed paths L1, . . . , LN (three in the illustrated example) nested one in the other. In particular, in one embodiment the closed paths are concentric circumferences and each second trench 6 extends on a portion of a respective closed path L1, . . . , LN. Second trenches 6 which extend along a same closed path are separated from each other by portions of the dielectric layer 3. In this manner, a first region 3a and a second region 3b of the dielectric layer 3, respectively internal to the second trenches 6 and comprised between the first trenches 5 and the second trenches 6, are connected to each other through the portions of the dielectric layer 3 which separate consecutive second trenches 6. It is understood, however, that second trenches might not be organized in closed paths and might otherwise be arranged to form anchors, according to design preferences. For example, in the embodiment of FIG. 4 the second trenches, here indicated by 6′, are aligned in rows.

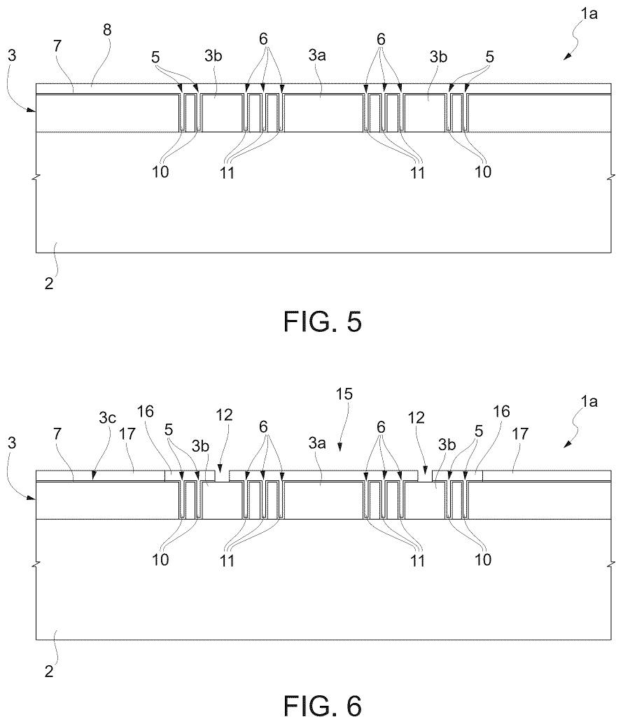

The microstructure wafer 1 is then covered with a stop layer 7 (FIG. 5), thin enough to coat the inside of the first trenches 5 and the second trenches 6 without filling them. The stop layer 7 is of a material with respect to which the silicon (or, in general, the material forming the substrate 2) is selectively etchable, for example alumina.

After the stop layer 7, a connection and anchoring layer 8, for example of polycrystalline silicon, is deposited on the microstructure wafer 1 and fills the first trenches 5 and the second trenches 6 forming anchoring rings or portion 10 and anchoring pins 11 respectively, in this case with portions of the stop layer 7 which coat the inside of the first trenches 5 and the second trenches 6. The anchoring pins 11, in particular, are organized in concentric arrays, corresponding to respective closed paths L1, . . . , LN. In each array, adjacent anchoring pins 11 are separated by portions of the dielectric layer 3. The dimensions of the second trenches 6 and the distances between consecutive second trenches 6 at least of the innermost array are selected so that the spaces between consecutive anchoring pins 11 may be sealed by a plasma deposition process, as detailed below. For example, the spacing between consecutive anchoring pins 11 may be between 1 μm and 5 μm.

Then (FIG. 6), the stop layer 7 and the connection and anchoring layer 8 are defined to open one or more windows 12 between the first region 3a of the dielectric layer 3 and the innermost of the anchoring rings 10 (which corresponds to the innermost of the first trenches 5), so as to expose part of the dielectric layer 3. In the embodiment of FIG. 6, in particular, a single window 12 having annular shape is opened on the second region 3b of the dielectric layer 3. Consequently, a crown portion of the dielectric layer 3, of a shape corresponding to the window 12, is exposed. Alternatively, a plurality of windows may be opened, for example circular and distributed along a circumference.

In a zone radially internal to the window 12, or more precisely over the first portion 3a of the dielectric layer 3 and over the anchoring pins 11 up to an inner edge of the window 12, remaining portions of the connection and anchoring layer 8 form an anchoring pad 13 bonded to the anchoring pins 11. In turn, the anchoring pad 13 forms an anchoring structure 15 with the anchoring pins 11. In practice, the anchoring pad 13 extends on a face 3c of the dielectric layer 3 opposite to the substrate 2; the anchoring pins 11 extend from the anchoring pad 13 to the substrate 2 perpendicular to the face 3c and along respective arcs of circumference parallel to the face 3c.

In this step, the connection and anchoring layer 8 is also shaped to form anchoring pads 16 and conductive lines 17 according to the design preferences for the microelectromechanical devices to be formed in the microstructure wafer 1.

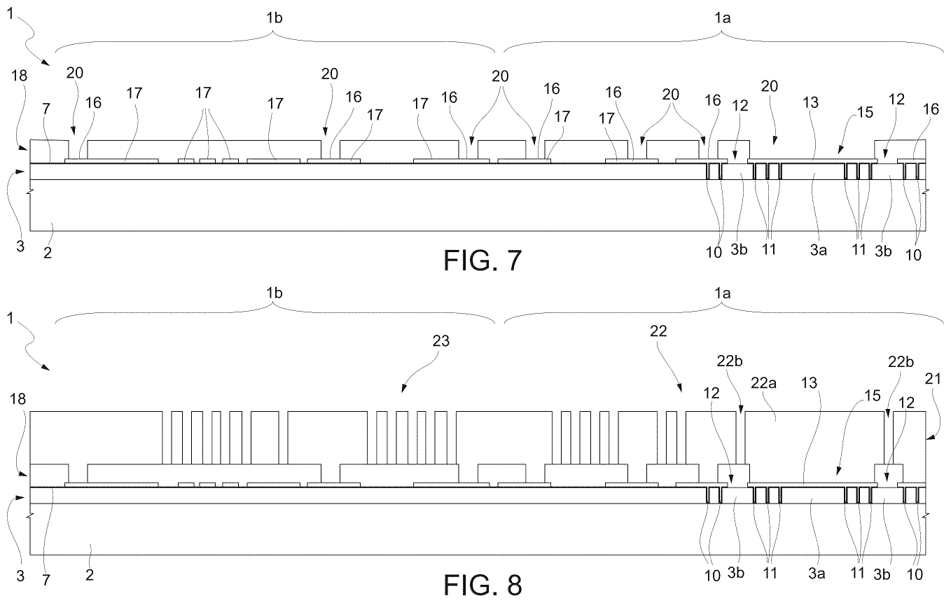

A sacrificial layer 18 of silicon oxide is then deposited on the microstructure wafer 1 (FIG. 7), which is in contact with the dielectric layer 3 through the window 12. The sacrificial layer 18 is selectively removed to form anchoring openings 20 over respective anchoring pads 16. Furthermore, one of the anchoring openings 20 exposes the anchoring pad 13 of the anchoring structure 15.

Starting from a seed layer (not shown), a structural layer 21 of polycrystalline silicon is formed on the microstructure wafer 1 (FIG. 8) by growth in an epitaxial reactor. The structural layer 21 contacts the anchoring pads 13, 16 through the anchoring openings 20. The structural layer 21 is then defined by an anisotropic trench etching to form fixed and movable parts of a gyroscope 22 in the first region 1a of the microstructure wafer 1 and an accelerometer 23 in the second region 1b. In particular, a fixed or stator portion 22a of the gyroscope 22 is anchored to the anchoring pad 13 of the anchoring structure 15 and is separated from the remaining part of the gyroscope 22 by gaps 22b. However, it is understood that the stator portion 22a of the gyroscope 22 may extend beyond the anchoring structure 15 and be in part anchored to the dielectric layer 3. Furthermore, the gaps 22b reach the portion of the sacrificial layer 18 which is connected to the second region 3a of the dielectric layer 3 through the windows 12.

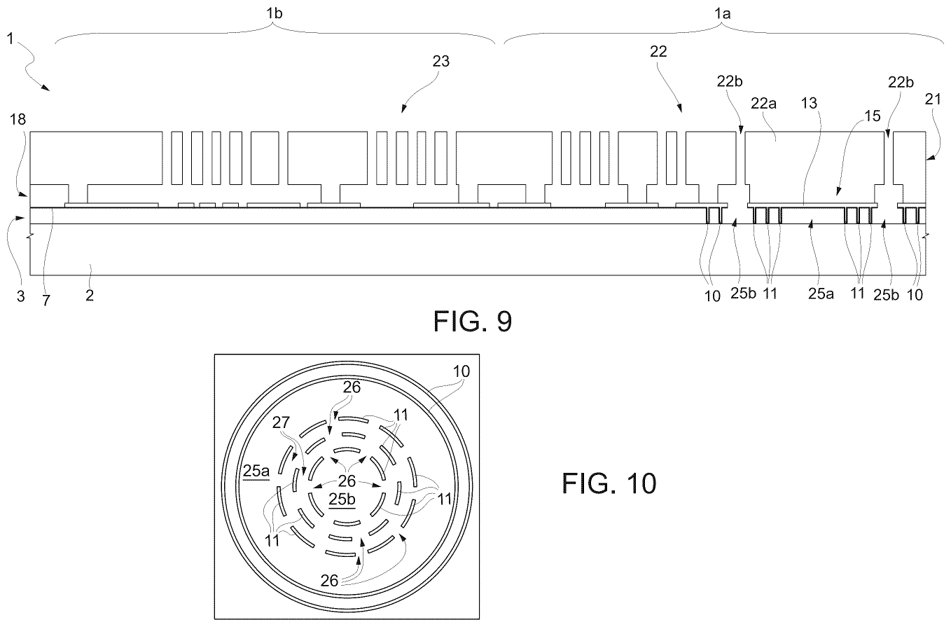

The sacrificial layer 18 is then removed where accessible to free the microstructures of the gyroscope 22 and the accelerometer 23, for example by etching in a hydrofluoric acid bath, as shown in FIG. 9. Furthermore, also the part of the dielectric layer 3 internal to the annular anchors 10, which is accessible through the window 12, is removed at the same time. The annular anchors 11, in this step, stop the removal of the dielectric layer 3. When the removal of the sacrificial layer 18 and the dielectric layer 3 is completed, a cavity 25 is defined radially inside the annular anchors 10 between the substrate and the stop layer 7. In particular, a first portion 25a of the cavity 25, radially internal to the anchoring pins 11, communicates fluidically with a second portion 25b of the cavity 25, radially comprised between the annular anchors 10 and the anchoring pins 11. The fluidic connection is obtained through passages 26 between adjacent anchoring pins 11 and channels 27 between concentric arrays of anchoring pins 11, as better illustrated in FIG. 10. In turn, after the sacrificial layer 18 has been removed the second portion 25b of the cavity 25 is fluidically coupled to the environment which surrounds the gyroscope 22 through the window 12 and the gaps 22b around the stator portion 22a.

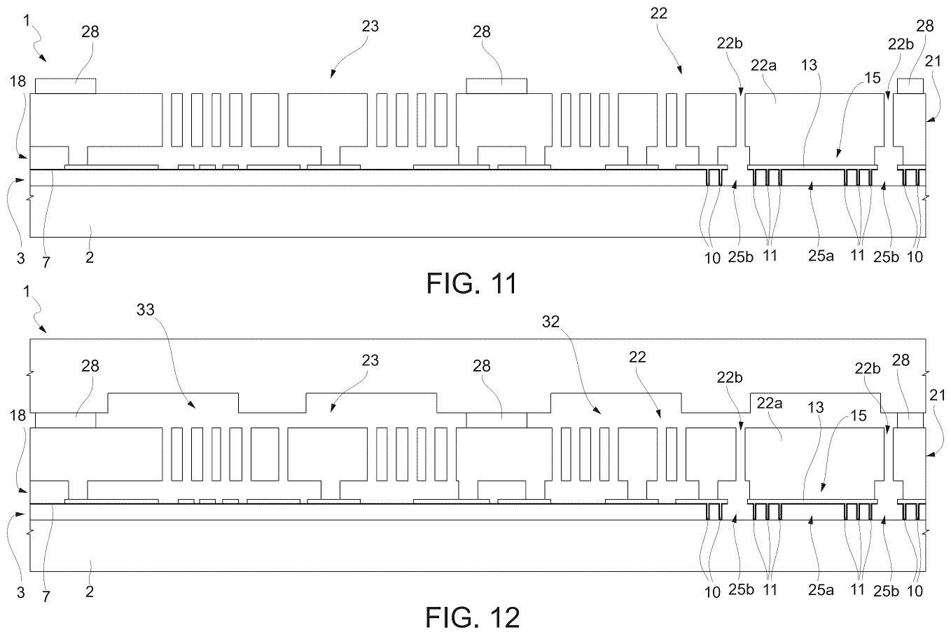

An adhesion layer 28 (FIG. 11) is then deposited on portions of the structural layer 21 along closed paths which surround the gyroscope 22 and the accelerometer 23. The adhesion layer 28 may be of any suitable sealing material and used in semiconductor manufacturing processes for wafer bonding, for example and not limited to glass frit, an Al—Ge eutectic alloy, Au—Sn, Au—In, Au—Si, Si—Si, Si—SiO2 alloys.

Then (FIG. 12), a cap wafer 30, preliminarily processed on an inner face according to the design preferences, is bonded to the microstructure wafer 1 in a controlled atmosphere at a first pressure P₁, forming a composite wafer 31. By adhering to the adhesion layer 28, the cap wafer 30 seals the gyroscope 22 and the accelerometer 23 respectively inside a first chamber 32 and a second chamber 33, both at the first pressure P₁. In one embodiment, the first pressure P₁ is a design operating pressure of the accelerometer 23, for example between 1 mbar and 5 bar.

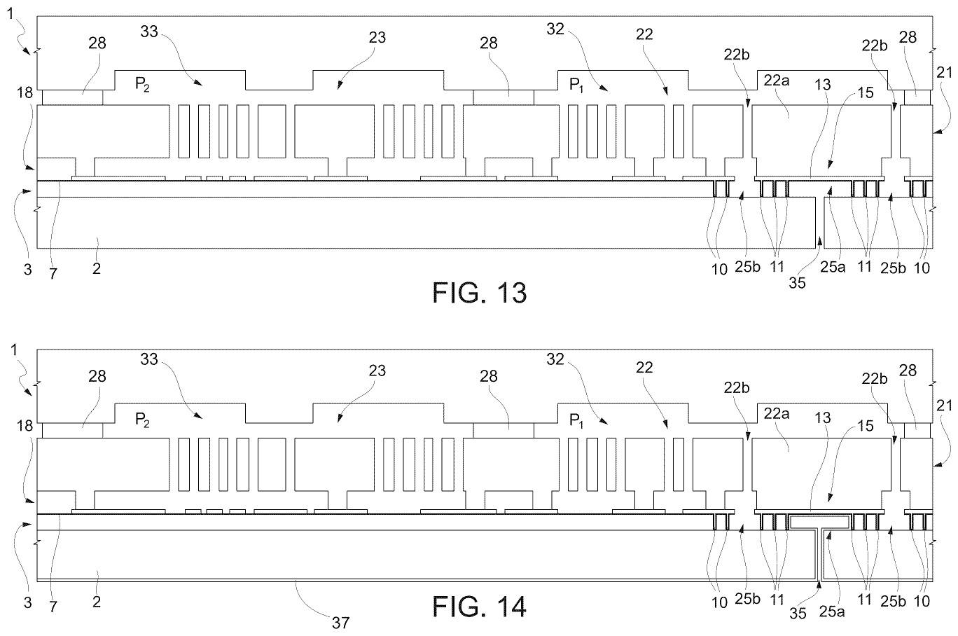

As shown in FIG. 13, the substrate 2 of the microstructure wafer 1 is then anisotropically etched through a back side 2a to form a channel 35 aligned with the first portion 25a of the cavity 25. In this step, the etching of the semiconductor material ends on the stop layer 7, which protects the structural layer 21, in particular the fixed or stator portion 22a of the gyroscope 22. In practice, therefore, a fluidic path is defined which puts the first chamber 32, where the gyroscope 22 is arranged, in communication with the outside through the window 12, the second portion 25b of the cavity 25, the passages 26 and the channels 27 between the anchoring pins 11, the first portion 25a of the cavity 25 and the channel 35.

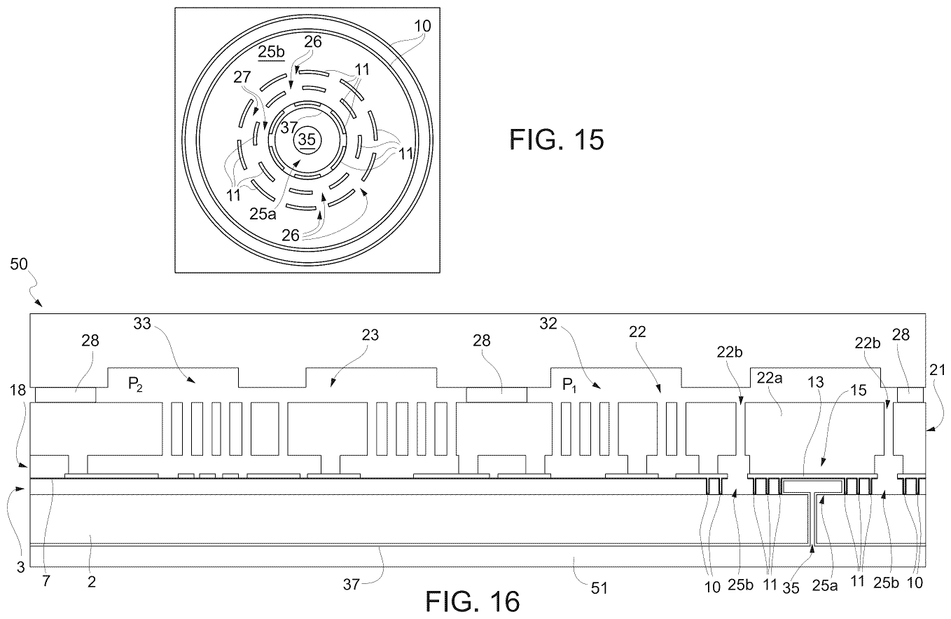

The composite wafer 31 is then placed in an environment at a second pressure P₂, different from the first pressure P₁ and lower in an embodiment, and is sealed (FIGS. 14 and 15). More precisely, a sealing layer 37 is formed on the back side 2a of the substrate 2, for example by PVD (Physical Vapor Deposition) or PECVD (Plasma-Enhanced Chemical Vapor Deposition) deposition, and penetrates inside the channel 35 and the first region 25a of the cavity 25. Due to the initial spacing between the second trenches 6 (and therefore between the adjacent anchoring pins 11 of the same array), the passages 26 between the anchoring pins 11 close for the deposition of the sealing layer 37 and the first portion 25a is fluidically insulated from the rest of the cavity 25 and from the first chamber 32. The first chamber 32 is therefore sealed at the second pressure P₂, which may be accurately set and maintained.

After final processing steps which may comprise thinning, grinding, definition of contacts and cleaning, the composite wafer 31 is finally diced and divided into dice, each of which comprises a microelectromechanical device 50 of the type illustrated in FIG. 16, where it is shown incorporated into a package 51. For example, in at least one embodiment, the package 51 is a molding compound, resin, or epoxy that partially or fully fills the channel 35.

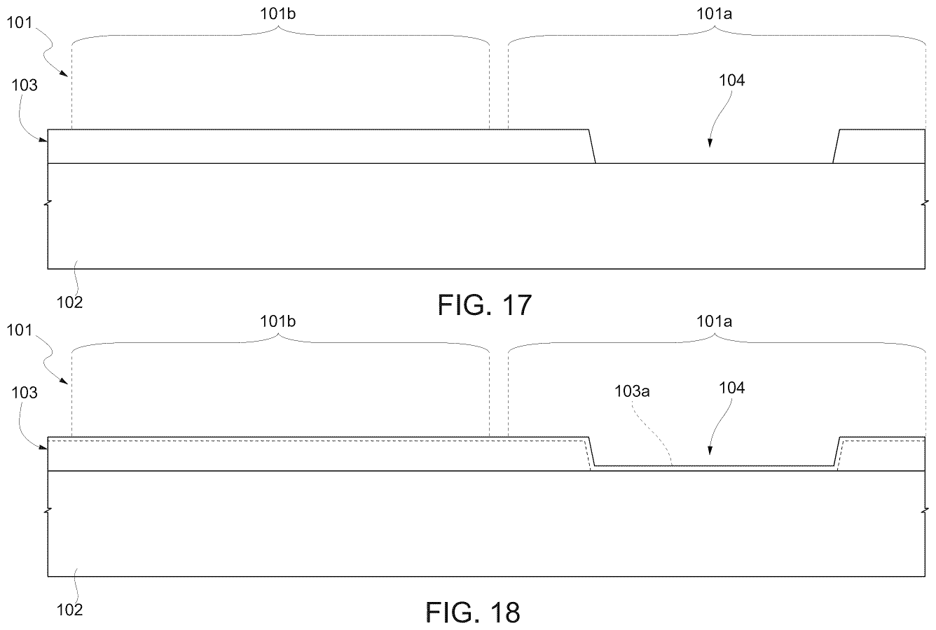

A different embodiment of the present disclosure will be described below with reference to FIGS. 17-30. A microstructure wafer 101 comprising a substrate 102 of semiconductor material, for example monocrystalline silicon, is intended to accommodate microstructures of microelectromechanical devices. In particular, a first region of the microstructure wafer 101, indicated by 101a, is intended to accommodate a first microelectromechanical sensor operating at a first pressure, for example a gyroscope, and a second region of the microstructure wafer 101, indicated by 101b, is intended to accommodate a second microelectromechanical sensor operating at a second pressure, higher than the first pressure, for example an accelerometer.

Initially, a dielectric layer 103, for example silicon oxide, is formed on the substrate 102 and selectively etched to open a window 104, for example circular, which exposes a portion of the substrate 102 in the first region 101a of the microstructure wafer.

Then (FIG. 18), the dielectric layer 103 is increased by, for example, 0.5 μm or less by thermal oxidation or deposition of further silicon oxide and covers the substrate 102.

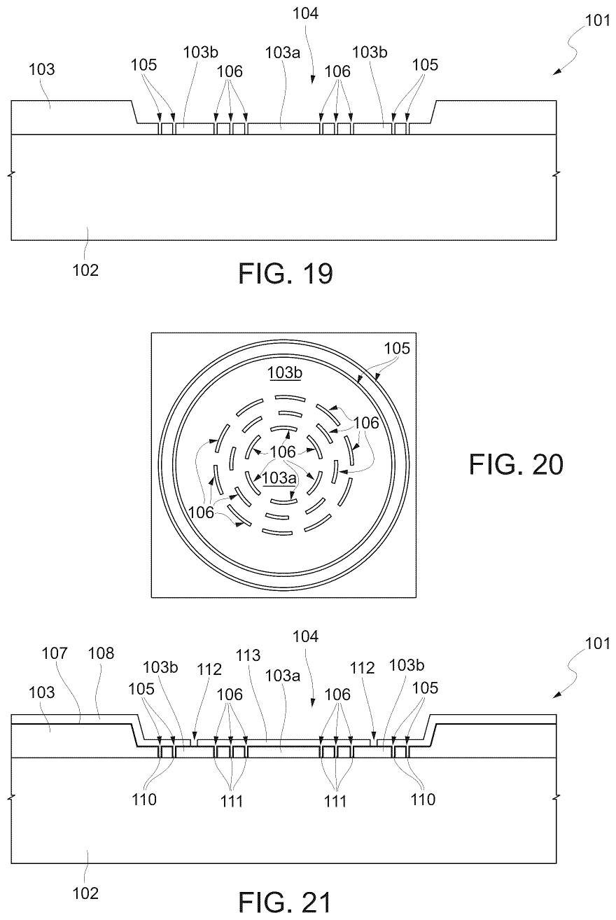

The dielectric layer 103 is selectively etched inside the window 105 to form first trenches 105 and second trenches 106 (FIGS. 19 and 20), which will then serve for the formation of anchors. The first trenches 105 extend continuously along respective closed paths nested one inside the other. In the embodiment described herein, in particular two circular and concentric first trenches 105 are opened.

The second trenches 106 are enclosed inside the first trenches 105 and, in one embodiment, are organized in arrays which extend on closed paths L1′, . . . , LN′ (three in the illustrated example) nested one in the other. In particular, in one embodiment the closed paths are concentric circumferences and each second trench 106 extends on a portion of a respective closed path L1′, . . . , LN′. Second trenches 106 which extend along a same closed path are separated from each other by portions of the dielectric layer 103. In this manner, a first region 103a and a second region 103b of the dielectric layer 103, respectively internal to the second trenches 106 and comprised between the first trenches 105 and the second trenches 106, are connected to each other through the portions of the dielectric layer 103 which separate consecutive second trenches 106.

The process then proceeds substantially as already described and will be briefly recalled.

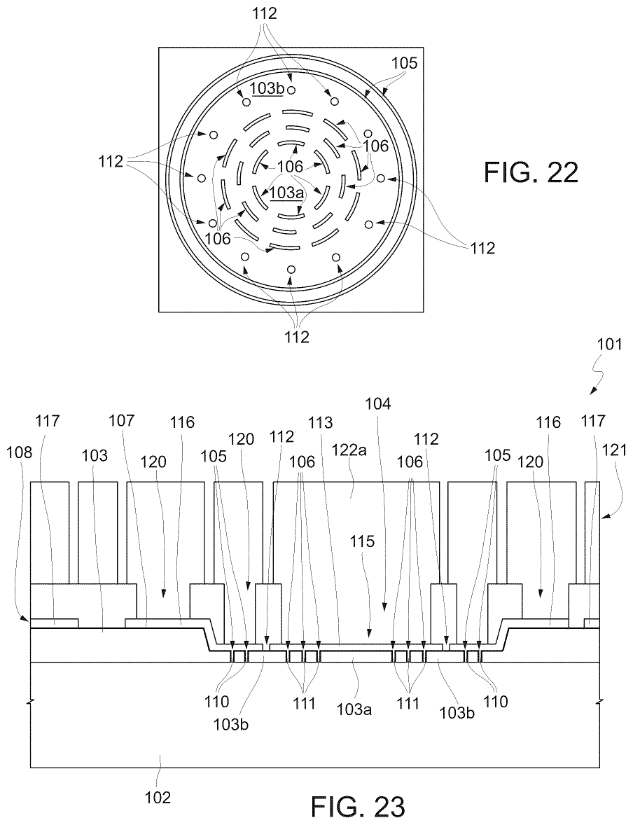

A stop layer 107, for example alumina, and a connection and anchoring layer 108 are deposited on the microstructure wafer 101 (FIGS. 21 and 22). The stop layer 107 coats the walls of the first trenches 105 and the second trenches 106, leaving a space therewithin which is filled by the connection and anchoring layer 108. Annular anchors 110 in the first trenches 105 and anchoring pins 111 in the second trenches 106 are thus formed. The anchoring pins 111 extend from the anchoring pad 113 to the substrate 102 perpendicular to the face 3c and along respective arcs of circumference parallel to the face 3c.

The stop layer 107 and the connection layer are etched to open windows 112 on the second region 103b of the dielectric layer 103, in this case a plurality of windows 112 distributed along a circumference between the innermost first trench 105 and the outermost array of second trenches 106 (FIG. 22).

A portion of the connection and anchoring layer 8 radially internal to the windows 112 forms an anchoring pad 113 bonded to the anchoring pin 111. In turn, the anchoring pad 113 forms an anchoring structure 115 with the anchoring pins 111. In practice, the anchoring pad 113 is depressed with respect to a face of the dielectric layer 103 opposite to the substrate 102.

The connection and anchoring layer 108 is also patterned to form anchoring pads 116 and conductive lines 117 according to the design preferences for the microelectromechanical devices to be formed in the microstructure wafer 101.

A sacrificial layer 118 of silicon oxide is then deposited on the microstructure wafer 101 (FIG. 23), which is in contact with the dielectric layer 103 through the windows 112 and is selectively removed to form anchoring openings 120 over respective anchoring pads 116. Furthermore, one of the anchoring openings 120 exposes the anchoring pad 113 of the anchoring structure 115. A structural layer 121 of polycrystalline silicon is formed on the microstructure wafer 101 in contact with the anchoring pads 113, 116 through the anchoring openings 120, by growth in an epitaxial reactor. The structural layer 121 is then patterned to form fixed and movable parts of a gyroscope 122 in the first region 101a of the microstructure wafer 101 and an accelerometer (not shown) in the second region 101b. In particular, a fixed or stator portion 122a of the gyroscope 122 is anchored to the anchoring pad 113 of the anchoring structure 115 and is separated from the remaining part of the gyroscope 122 by gaps 122b which reach the portion of the sacrificial layer 118 which is connected to the second region 103a of the dielectric layer 103 through the windows 112.

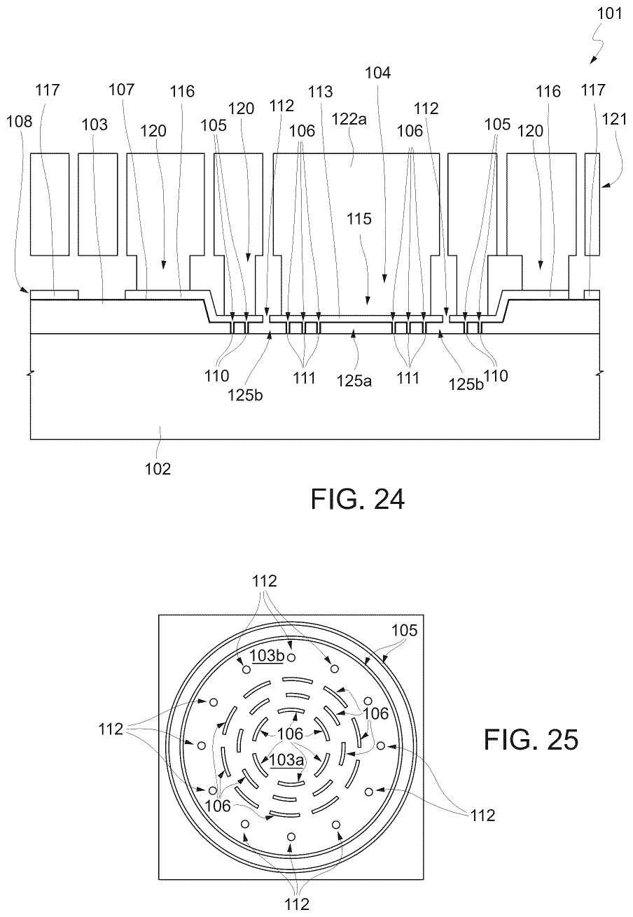

The sacrificial layer 118 is then removed where accessible to release the microstructures of the gyroscope 122 and the accelerometer, as shown in FIG. 24. At the same time, the part of the dielectric layer 103 internal to the annular anchors 110 is also removed through the window 112. A cavity 125 is thus defined radially inside the annular anchors 110. A first portion 125a of the cavity 125, radially internal to the anchoring pins 111, communicates fluidically with a second portion 125b of the cavity 125, radially comprised between the annular anchors 110 and the anchoring pins 111, through passages 126 between adjacent anchoring pins 111 and channels 127 between concentric arrays of anchoring pins 111, as better illustrated in FIG. 25. Furthermore, the second portion 125b of the cavity 125 is fluidically coupled to the environment which surrounds the gyroscope 122 through the window 112 and the gaps around the fixed portion 122a.

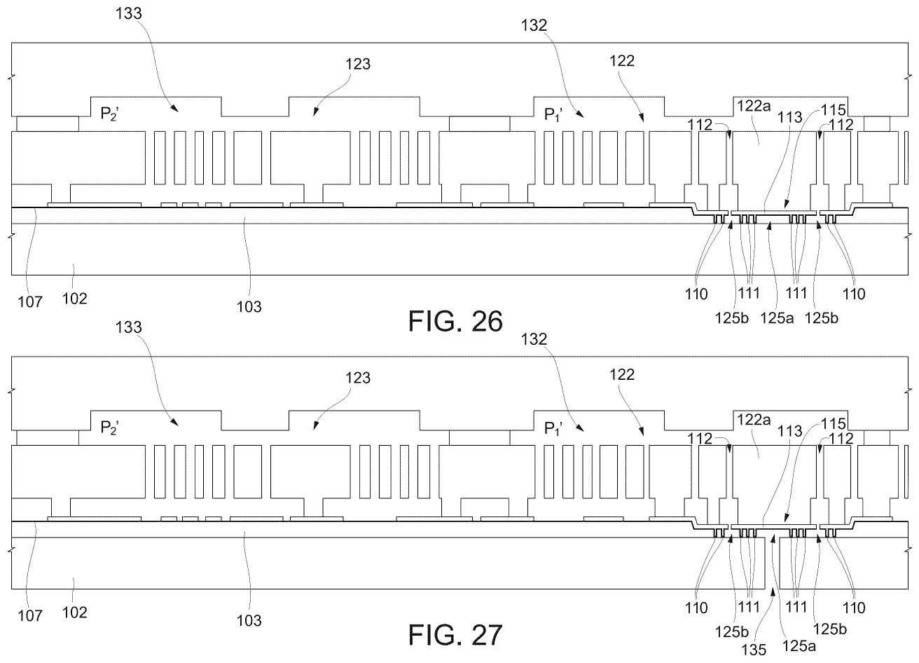

With reference to FIG. 26, a cap wafer 130 is bonded to the microstructure wafer 101 using an adhesion layer 128 to seal the gyroscope 122 and the accelerometer (here indicated by 123) respectively inside a first chamber 32 and a second chamber 33, both at a first pressure P₁′.

The substrate 102 of the microstructure wafer 1 is then etched from the back in an anisotropic manner to form a channel 135 aligned with the first portion 125a of the cavity 125 (FIG. 27), thus forming a fluidic path that put the first chamber 132, where the gyroscope 122 is arranged, in communication with the outside through the window 112, the second portion 125b of the cavity 125, the passages 126 and the channels 127 between the anchoring pins 111, the first portion 125a of the cavity 125 and the channel 135. In this step, the etching of the semiconductor material ends on the stop layer 107, which protects the structural layer 121, in particular the fixed portion 122a of the gyroscope 122.

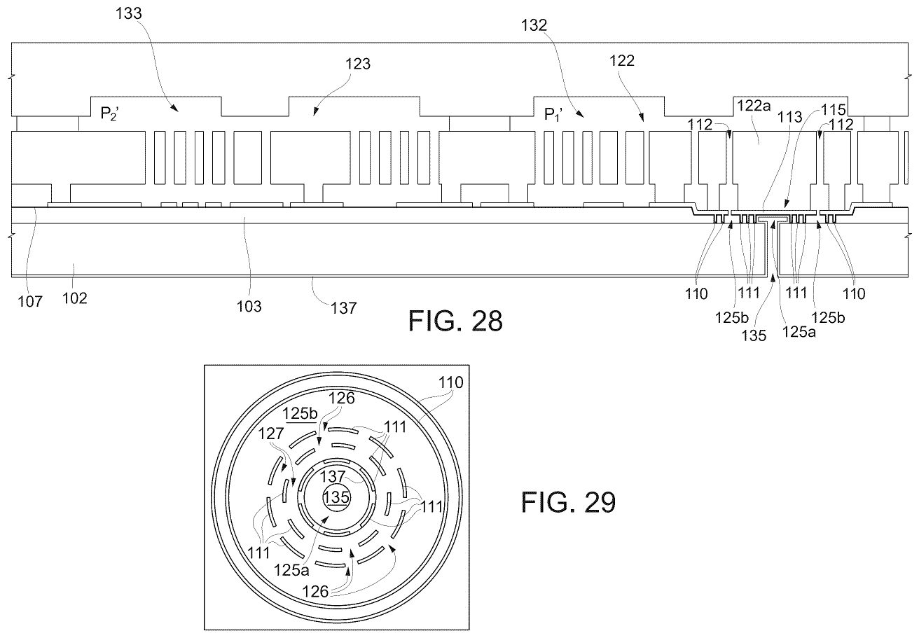

The composite wafer 131 is then placed in an environment at a second pressure P₂′, lower than the first pressure P₁′, and is sealed (FIGS. 28 and 29). More precisely, a sealing layer 137 is formed on the back of the substrate 102 by PVD or PECVD deposition and penetrates inside the channel 135 and the first region 125a of the cavity 125. The passages 126 between the anchoring pins 111 close for the deposit of the sealing layer 137 and the first portion 125a is fluidically insulated from the rest of the cavity 125 and the first chamber 132. The first chamber 132 is therefore sealed at the second pressure P₂′, which may be accurately set and maintained.

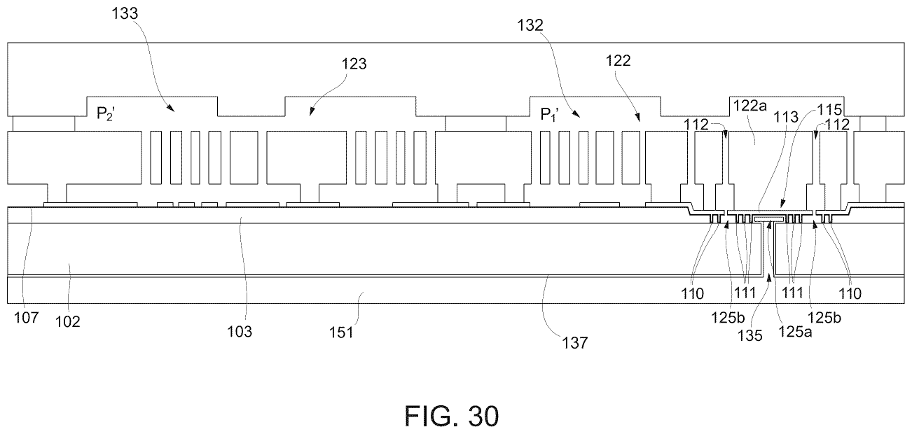

After final processing steps, the composite wafer 131 is finally diced and divided into dice, each of which comprises an integrated microelectromechanical device 150 of the type illustrated in FIG. 30, where it is shown incorporated into a package 151. For example, in at least one embodiment, the package 151 is a molding compound, resin, or epoxy that partially or fully fills the channel 35.

The process described advantageously allows two different microelectromechanical devices to be sealed in respective chambers at respective accurately controlled pressures, without using getter. The absence of getter, in particular, is advantageous for several reasons. Firstly, space in one of the chambers is clearly saved. This is highly desirable, given the ever-increasing trend towards miniaturization of devices. Secondly, the risk of early getter activation, which might alter the pressure in one or both chambers unpredictably, is completely eliminated. As it has been seen, in fact, the early activation during the steps in which the cap wafer is bonded to the microstructure wafer may cause both the absorption of gas from the high-pressure chamber by cross-talk and the saturation of the getter and therefore a higher-than-expected pressure in the low-pressure chamber. In turn, pressure variations in the chambers may affect the performance of microelectromechanical devices in an uncontrolled manner and, in any case, the actual operating conditions will be different from the preferred design conditions.

The disclosure instead allows for very accurate control of the pressure in both chambers. The first chamber is in fact sealed exactly at the first pressure and no fluidic connection with the outside is established any longer. In particular, the first chamber is already definitively sealed when the second chamber is equalized at the second pressure and then sealed.

Sealing the second chamber at lower pressure by using PVD or PECVD deposition is further advantageous because it allows the low pressure typically used for this type of processes to be exploited. This condition is particularly suitable for devices operating at very low pressure (in the order of microbars), such as geophones or bolometers.

The process may be implemented mostly using processing steps in any case envisaged for the manufacturing of integrated microelectromechanical devices, simply by suitably designing the etching masks used. Dedicated steps are used in practice only for opening the channel from the back of the composite wafer, without therefore interfering with the processing steps on the front. The process according to the disclosure therefore does not entail significant increases in complexity and costs, in the face of a notable improvement in performance and a reduction in rejects.

Furthermore, a dedicated etching is not necessary to remove residual portions of the stop layer.

Finally, it is clear that modifications and variations may be made to the microelectromechanical accelerometer described, without departing from the scope of the present disclosure.

For example, the cap wafer may be bonded to the microstructure wafer under low pressure conditions and, after putting one of the chambers (e.g., a chamber containing an accelerometer) in communication with the outside through a channel in the substrate and the anchor structures, seal under high pressure conditions.

Furthermore, a plurality of fluidic paths between the outside and one of the two sealed chambers may be opened with the described techniques, in numbers and positions selected according to design preferences.

According to further variants, the stop layer may be selectively removed before depositing the connection layer and left only in the position corresponding to the first portion of the cavity and the channel.

At least one embodiment of a process for manufacturing microelectromechanical devices of the present disclosure is summarized as including: on a first semiconductor wafer (1; 101) including a substrate (2; 102) of semiconductor material, forming a dielectric layer (3; 103), a structural layer (21; 121) and a stop layer (7; 107) between the dielectric layer (3; 103) and the structural layer (21; 121), the substrate (2; 102) being selectively etchable with respect to the stop layer (7; 107); forming a first microelectromechanical device (22; 122) and a second microelectromechanical device (23; 123) in the structural layer (21; 121); sealing the first microelectromechanical device (22; 122) and the second microelectromechanical device (23; 123) respectively in a first chamber (32; 132) and in a second chamber (33; 133) at a first pressure (P₁; P₁′); fluidically coupling the first chamber (32; 132) to an external environment through the substrate (2; 102); and sealing the first chamber (32; 132) at a second pressure (P₂; P₂′) different from the first pressure (P₁; P₁′); wherein fluidically coupling includes: forming a cavity (25; 125) fluidically coupled to the first chamber (32; 132) in the dielectric layer (3; 103) between the substrate (2; 102) and a portion of the stop layer (7; 107); forming a channel (35; 135) through the substrate (2; 102) in a position corresponding to the cavity (25; 125) and the portion of the stop layer (7; 107); and ending the etching of the substrate (2; 102) against the stop layer (7; 107).

In at least one embodiment, the process includes forming an anchoring structure (15; 115) extending through the cavity and configured to anchor a fixed portion (22a; 122a) of the first microelectromechanical device (22; 122) to the substrate.

In at least one embodiment, the anchoring structure (15; 115) delimits, in the cavity (25; 125), an inner first portion (25a; 125a) and an outer second portion (25b; 125b) and forms fluidic passages (26, 27; 126, 127) between the first portion (25a; 125a) and the second portion (25b; 125b) of the cavity (25; 125).

In at least one embodiment, forming the anchoring structure (15; 115) includes: opening first trenches (5; 105) in the dielectric layer (3; 103) to the substrate (2; 102), the first trenches (5; 105) extending continuously along respective first closed paths nested one inside the other; opening second trenches (6; 106) in the dielectric layer (3; 103) to the substrate (2; 102), the second trenches (6; 106) being enclosed inside the first trenches (5; 105) and extending on portions of respective second closed paths nested one inside the other; wherein a first region (3a; 103a) of the dielectric layer (3; 103), internal to the second trenches (6; 106) and of a shape corresponding to the first portion (25a; 125a) of the cavity (25; 15), and a second region (3b; 103b) of the dielectric layer (3; 103), including between the first trenches (5; 105) and the second trenches (6; 106) and of a shape corresponding to the second portion (25b; 125b) of the cavity (25; 15), are connected to each other through portions of the dielectric layer (3; 103) separating second consecutive trenches (6; 106).

In at least one embodiment, forming the anchoring structure (15; 115) includes forming a semiconductor connection and anchoring layer (8; 108) on the stop layer (7; 107), so as to fill the first trenches (5; 105) and the second trenches (6; 106) and respectively form annular first anchoring elements (10; 110) and second anchoring elements (11; 111); patterning the connection and anchoring layer (8; 108) so as to define an anchoring pad (13; 113) bonded to the second anchoring elements (11; 111) over the first region (3a; 103a) of the dielectric layer (3; 103).

In at least one embodiment, the process includes selectively removing the connection and anchoring layer (8; 108) and the stop layer (7; 107) so as to open at least one window (12; 112) on the second region (3b; 103b) of the dielectric layer (3; 103) around the anchoring structure (15; 115) and expose a portion of the dielectric layer (3; 103) of a shape corresponding to the window (12; 112).

In at least one embodiment, the process includes forming a dielectric sacrificial layer (18; 118) in contact with the second region (3b; 103b) of the dielectric layer (3; 103) through the at least one window (12; 112).

In at least one embodiment, the sacrificial layer (18; 118) is formed on the stop layer (7; 107).

In at least one embodiment, the process includes removing the sacrificial layer (18; 118) selectively over the anchoring pad (13; 113); and forming a semiconductor structural layer (21; 121) on the sacrificial layer and in contact with the anchoring pad (13; 113); wherein forming the first microelectromechanical device (22; 122) and the second microelectromechanical device (23; 123) includes etching the structural layer (21; 121) in an anisotropic manner to the sacrificial layer (18; 118).

In at least one embodiment, forming the cavity (25; 125) includes removing the sacrificial layer (18; 118) and removing the first region (3a; 103a) and the second region (3b; 103b) of the dielectric layer (3; 103) through the at least one window (12; 112).

In at least one embodiment, the channel (35; 135) is aligned with the first portion (25a; 125a) of the cavity (25; 125).

In at least one embodiment, sealing the first chamber (32; 132) at the second pressure (P₂; P₂′) includes depositing a sealing layer (37; 137) on a back side (2a; 102a) of the substrate (2; 102) and through the channel (35; 135).

In at least one embodiment, sealing the first chamber (32; 132) at the second pressure (P₂; P₂′) includes fluidically insulating the first portion (25a; 125a) from the rest of the cavity (25; 125) and from the first chamber (32; 132).

In at least one embodiment, sealing the first chamber (32; 132) at the second pressure (P₂; P₂′) includes closing the fluidic passages (26, 27; 126, 127) between the first portion (25a; 125a) and the second portion (25b; 125b) of the cavity (25; 125).

In at least one embodiment, sealing the first microelectromechanical device (22; 122) and the second microelectromechanical device (23; 123) includes bonding a second semiconductor wafer (30; 130) to the first semiconductor wafer (1; 101).

At least one embodiment of a microelectromechanical device of the present disclosure is summarized as including: a substrate (2; 102) of semiconductor material; a dielectric layer (3; 103) on the substrate (2; 102); a structural layer (21; 121) of semiconductor material on the dielectric layer (3; 103); a stop layer (7; 107) interposed between the dielectric layer (3; 103) and the structural layer (21; 121), the substrate (2; 102) being selectively etchable with respect to the stop layer (7; 107); in the structural layer (21; 121), a first microelectromechanical device (22; 122) and a second microelectromechanical device (23; 123) sealed respectively in a first chamber (32; 132) at a first pressure (P₁; P₁′) and in a second chamber (33; 133) at a second pressure (P₂; P₂′), different from the first pressure (P₁; P₁′); a channel (35; 135) traversing the substrate (2; 102); in the dielectric layer (3; 103) between the substrate (2; 102) and a portion of the stop layer (7; 107), a first cavity (25a; 125a) fluidically coupled to the channel (35), a second cavity (25b; 125b) fluidically coupled to the first chamber (32; 132) and fluidic passages (26, 27; 126, 127) between the first cavity (25a; 125a) and the second cavity (25b; 125b); and a sealing layer (37; 137) which closes the fluidic passages (26, 27; 126, 127) and fluidically insulates the first cavity (25a; 125a) from the second cavity (25b; 125b).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A process, comprising:
on a first semiconductor wafer comprising a substrate of semiconductor material, forming a dielectric layer, a structural layer and a stop layer between the dielectric layer and the structural layer, the substrate being selectively etchable with respect to the stop layer;
forming a first microelectromechanical device and a second microelectromechanical device in the structural layer;
sealing the first microelectromechanical device and the second microelectromechanical device respectively in a first chamber and in a second chamber at a first pressure;
fluidically coupling the first chamber to an external environment through the substrate; and
sealing the first chamber at a second pressure different from the first pressure;
wherein fluidically coupling comprises:
forming a cavity fluidically coupled to the first chamber in the dielectric layer between the substrate and a portion of the stop layer;
forming a channel through the substrate in a position corresponding to the cavity and the portion of the stop layer; and
ending the etching of the substrate against the stop layer.

2. The process according to claim 1, comprising forming an anchoring structure extending through the cavity and configured to anchor a fixed portion of the first microelectromechanical device to the substrate.

3. The process according to claim 2, wherein the anchoring structure delimits, in the cavity, an inner first portion and an outer second portion and forms fluidic passages between the first portion and the second portion of the cavity.

4. The process according to claim 3, wherein forming the anchoring structure comprises:
opening first trenches in the dielectric layer to the substrate, the first trenches extending continuously along respective first closed paths nested one inside the other;
opening second trenches in the dielectric layer to the substrate, the second trenches being enclosed inside the first trenches and extending on portions of respective second closed paths nested one inside the other;
wherein a first region of the dielectric layer, internal to the second trenches and of a shape corresponding to the first portion of the cavity, and a second region of the dielectric layer, comprised between the first trenches and the second trenches and of a shape corresponding to the second portion of the cavity, are connected to each other through portions of the dielectric layer separating second consecutive trenches.

5. The process according to claim 4, wherein forming the anchoring structure comprises forming a semiconductor connection and anchoring layer on the stop layer, so as to fill the first trenches and the second trenches and respectively form annular first anchoring elements and second anchoring elements;
patterning the connection and anchoring layer so as to define an anchoring pad bonded to the second anchoring elements over the first region of the dielectric layer.

6. The process according to claim 5, comprising selectively removing the connection and anchoring layer and the stop layer so as to open at least one window on the second region of the dielectric layer around the anchoring structure and expose a portion of the dielectric layer of a shape corresponding to the window.

7. The process according to claim 6, comprising forming a dielectric sacrificial layer in contact with the second region of the dielectric layer through the at least one window.

8. The process according to claim 7, wherein the sacrificial layer is formed on the stop layer.

9. The process according to claim 7, comprising:
removing the sacrificial layer selectively over the anchoring pad; and
forming a semiconductor structural layer on the sacrificial layer and in contact with the anchoring pad;
wherein forming the first microelectromechanical device and the second microelectromechanical device comprises etching the structural layer in an anisotropic manner to the sacrificial layer.

10. The process according to claim 9, wherein forming the cavity comprises removing the sacrificial layer and removing the first region and the second region of the dielectric layer through the at least one window.

11. The process according to claim 3, wherein the channel is aligned with the first portion of the cavity.

12. The process according to claim 11, wherein sealing the first chamber at the second pressure comprises depositing a sealing layer on a back side of the substrate and through the channel.

13. The process according to claim 3, wherein sealing the first chamber at the second pressure comprises fluidically insulating the first portion from the rest of the cavity and from the first chamber.

14. The process according to claim 3, wherein sealing the first chamber at the second pressure comprises closing the fluidic passages between the first portion and the second portion of the cavity.

15. The process according to claim 1, wherein sealing the first microelectromechanical device and the second microelectromechanical device comprises bonding a second semiconductor wafer to the first semiconductor wafer.

16. A device, comprising:
a substrate of semiconductor material;
a dielectric layer on the substrate;
a structural layer of semiconductor material on the dielectric layer;
a stop layer interposed between the dielectric layer and the structural layer the substrate being selectively etchable with respect to the stop layer;
in the structural layer, a first microelectromechanical device and a second microelectromechanical device sealed respectively in a first chamber at a first pressure and in a second chamber at a second pressure, different from the first pressure;
a channel traversing the substrate;
in the dielectric layer between the substrate and a portion of the stop layer, a first cavity fluidically coupled to the channel, a second cavity fluidically coupled to the first chamber and fluidic passages between the first cavity and the second cavity; and
a sealing layer which closes the fluidic passages and fluidically insulates the first cavity from the second cavity.

17. The microelectromechanical device according to claim 16, further comprising:
an anchoring pad overlapping the channel and the first cavity; and
a plurality of anchoring pins extending from the anchoring pad to the substrate, the anchoring pins being spaced radially outward from the channel.

18. A device, comprising:
a substrate of semiconductor material, the substrate including a first surface and a second surface opposite to the first surface;
an anchoring structure including:
a plurality of anchoring pins coupled to the first surface of the substrate, the plurality of anchoring pins extend outward from the first surface of the substrate; and
an anchoring pad coupled to the plurality of anchoring pins and spaced apart from the first surface of the substrate by the plurality of anchoring pins;
a fixed portion coupled to the anchoring pad;
a first cavity overlapped by the anchoring pad, between the anchoring pad and the first surface of the substrate, and spaced inward from the plurality of pins;
a channel extending into the second surface of the substrate to the cavity;
a sealing layer at least partially filling the cavity and the channel; and
a second cavity spaced outward from the plurality of anchoring pins.

19. The device of claim 18, further comprising a plurality of fluidic passageways defined between the plurality of anchor pins fluidically coupling the first cavity to the second cavity.

20. The device of claim 18, further comprising an anchoring portion that is spaced outward from the plurality of anchoring pins and is spaced outward from the second cavity.
